(19) United States
(12) Patent Application Publication
(10) Pub. No.: US 2013/0094312 A1
(43) Pub. Date: Apr. 18, 2013

(54) VOLTAGE SCALING DEVICE OF SEMICONDUCTOR MEMORY

(71) Applicants: SOON-BOK JANG, SEOUL (KR); JONG-UK SONG, SEOUL (KR); YOUNG-WOOK KIM, GUNPO-SI (KR); HWA-SEOK OH, YONGIN-SI (KR)

(72) Inventors: SOON-BOK JANG, SEOUL (KR); JONG-UK SONG, SEOUL (KR); YOUNG-WOOK KIM, GUNPO-SI (KR); HWA-SEOK OH, YONGIN-SI (KR)

(73) Assignee: SAMSUNG ELECTRONICS CO., LTD., SUWON-SI (KR)

(21) Appl. No.: 13/584,849

(22) Filed: Aug. 14, 2012

(30) Foreign Application Priority Data
Oct. 18, 2011 (KR) 10-2011-0106638

(51) Int. Cl. G11C 7/00; H01L 35/00

(52) U.S. Cl. 365/194; 327/513

(57) ABSTRACT

A voltage scaling device of a semiconductor memory device, the voltage scaling device including: a delay tester for determining the number of delay cells of a delay locked loop (DLL) required to cumulatively delay a clock signal having a constant frequency, and which is input to the DLL, by one clock period; a temperature sensor for measuring the temperature of the semiconductor memory device; and a voltage regulator for regulating a supply voltage of a voltage source which provides a chip voltage to the semiconductor memory device in response to the temperature measured by the temperature sensor and a locking value corresponding to the number of delay cells calculated by the delay tester.

### CROSS-REFERENCE TO RELATED APPLICATIONS

This application claims the benefit of Korean Patent Application No. 10-2011-0106638, filed on Oct. 18, 2011, in the Korean Intellectual Property Office, the disclosure of which is incorporated herein in its entirety by reference.

### BACKGROUND

The inventive concept relates to a voltage scaling device of a semiconductor memory, and more particularly, to a voltage scaling device of a semiconductor memory, which controls a voltage through a delay locked loop (DLL).

It is necessary to supply a stable voltage to the inside of a chip in a semiconductor product. Accordingly, it is necessary to monitor an internal voltage of the chip to insure that the stable voltage is provided.

### SUMMARY

The inventive concept provides a voltage scaling device which senses a voltage variation inside a chip by using a delay locked loop (DLL) and a temperature sensor and supplies a stable voltage by feeding back the sensed voltage variation to a voltage supply source.

According to an aspect of the inventive concept, there is provided a voltage scaling device of a semiconductor memory device. The voltage scaling device includes: a delay tester configured to determine the number of delay cells of a delayed locked loop (DLL) required to cumulatively delay a clock signal having a constant frequency, and which is input to the DLL, by one clock period; a temperature sensor configured to measure the temperature of the semiconductor memory device; and a voltage regulator configured to regulate a supply voltage of a voltage source which provides a chip voltage to the semiconductor memory device in response to the temperature measured by the temperature sensor and a locking value corresponding to the number of delay cells determined by the delay tester.

The supply voltage of the semiconductor memory device may be decreased if the number of delay cells required to cumulatively delay the clock signal by one clock period increases, and the supply voltage of the semiconductor memory device may be increased if the number of delay cells required to cumulatively delay the clock signal by one clock period decreases.

When the number of delay cells required to cumulatively delay the clock signal by one clock period is constant, the voltage regulator may decrease the supply voltage of the semiconductor memory device if the temperature measured by the temperature sensor increases and may increase the supply voltage of the semiconductor memory device if the temperature measured by the temperature sensor decreases.

The delay tester may repeatedly determine the number of delay cells required to cumulatively delay the clock signal by one clock period, and the temperature sensor may measure the temperature of the semiconductor memory device when the number of delay cells required to cumulatively delay the clock signal by one clock period, which is determined at a second time, is different from the number of delay cells required to cumulatively delay the clock signal by one clock period, which is determined at a first time before the second time.

The temperature sensor may measure the temperature of the semiconductor memory device when the number of delay cells required to cumulatively delay the clock signal by one clock period is different from a reference number of delay cells.

The delay tester may periodically determine, at predetermined periods, the number of delay cells required to cumulatively delay the clock signal by one clock period, and the temperature sensor may measure, at the same predetermined periods, the temperature of the semiconductor memory device.

The voltage regulator may include a look-up table for storing reference supply voltage values corresponding to different numbers of delay cells required to cumulatively delay the clock signal by at least one clock period, and a sensed temperature, and may regulate the supply voltage with reference to the look-up table.

The look-up table may be stored in the semiconductor memory device during the manufacture of the semiconductor memory device.

The look-up table may be configured to be set by a user.

The voltage regulator may regulate the supply voltage within a predetermined voltage range, and the predetermined range may vary corresponding to the temperature measured by the temperature sensor.

The DLL may include a plurality of delay buffers and a multiplexer connected to the plurality of delay buffers, wherein the multiplexer outputs the number of delay buffers which are required to delay the clock signal by one clock period.

The semiconductor memory device may include a NAND flash memory.

According to another aspect of the inventive concept, there is provided a semiconductor memory device including: a controller including a voltage scaling device; and a cell array receiving a voltage from the controller. The voltage scaling device includes: a delay tester configured to determine the number of delay cells required to cumulatively delay a clock signal having a constant frequency, and which is input to the DLL, by one clock period; a temperature sensor configured to measure the temperature of the semiconductor memory device; and a voltage regulator configured to regulate a supply voltage of a voltage source which provides a chip voltage to the semiconductor memory device in response to the temperature measured by the temperature sensor and a locking value corresponding to the number of delay cells determined by the delay tester.

The supply voltage of the semiconductor memory device may be decreased if the number of delay cells required to cumulatively delay the clock signal by one clock period increases, and the supply voltage of the semiconductor memory device may be increased if the number of delay cells required to cumulatively delay the clock signal by one clock period decreases.

When the number of delay cells required to cumulatively delay the clock signal by one clock period is constant, the voltage regulator may decrease the supply voltage of the semiconductor memory device if the temperature measured by the temperature sensor increases and may increase the supply voltage of the semiconductor memory device if the temperature measured by the temperature sensor decreases.

According to another aspect of the inventive concept, an integrated circuit comprises an input terminal configured to receive a chip voltage; an output terminal configured to output a regulation signal for regulating a supply voltage of a voltage source which provides the chip voltage to the integrated circuit; and voltage scaling device. The voltage scaling device comprises: a delay tester including a delay locked loop (loop) having a cascaded series of delay cells each having a unit delay, wherein the delay tester is configured to receive at its input a clock signal having a constant frequency and to cumulatively delay the clock signal as it passes through the cascaded series of delay cells, and wherein the delay tester is further configured to determine a number of the delay cells through which the clock signal passes until it is delayed by at least one clock period; a temperature sensor configured to determine a temperature of the integrated circuit; and a voltage regulator which is configured to produce the regulation signal in response to the temperature determined by the temperature sensor and further in response to the number of the delay cells through which the clock signal passes until it is delayed by at least one clock period.

The delay tester may be further configured to compare the number of the delay cells through which the clock signal passes until it is delayed by at least one clock period with a reference number of delay cells, and to output to the voltage regulator a lock value signal indicating a difference between the number of the delay cells through which the clock signal passes until it is delayed by at least one clock period and the reference number of delay cells, and wherein the voltage regulator produces the regulation signal in response to the lock value signal.

The temperature sensor may be configured to measure the temperature of the integrated circuit only when the number of the delay cells through which the clock signal passes until it is delayed by at least one clock period is different than the reference number of delay cells.

The delay tester may be further configured to compare the number of the delay cells through which the clock signal passes until it is delayed by at least one clock period with a previously-determined number of the delay cells through which the clock signal previously passed until it was delayed by at least one clock period, and to output to the voltage regulator a lock value signal indicating a difference between the number of the delay cells through which the clock signal passes until it is delayed by at least one clock period and the previously-determined number of the delay cells through which the clock signal previously passed until it was delayed by at least one clock period, and wherein the voltage regulator produces the regulation signal in response to the lock value signal.

The voltage regulator may comprise a look-up table storing a plurality of reference supply voltage values, and wherein the voltage regulator selects one of the stored reference supply values in response to the temperature determined by the temperature sensor and further in response to the number of the delay cells through which the clock signal passes until it is delayed by at least one clock period, and which is further configured to produce the regulation signal so as to cause the supply voltage of the voltage source to become equal to the selected reference supply value.

### BRIEF DESCRIPTION OF THE DRAWINGS

Exemplary embodiments of the inventive concept will be more clearly understood from the following detailed description taken in conjunction with the accompanying drawings in which:

FIG. 1A is a block diagram illustrating a voltage scaling device according to an embodiment of the inventive concept;

FIG. 1B illustrates a semiconductor memory device including the voltage scaling device of FIG. 1A.

FIG. 2 illustrates delay buffers of a delay locked loop (DLL);

FIGS. 3A through 3G illustrate clock signals of input terminals or output terminals of the delay buffers of FIG. 2;

FIGS. 4A and 4B are diagrams for explaining a process of decreasing a level of a supply voltage of a voltage source when the level of the chip voltage received by a chip is greater than that of a reference chip voltage (that is, when the supply voltage is too high or higher than desired);

FIGS. 5A and 5B are diagrams for explaining a process of increasing a level of a supply voltage of a voltage source when the level of the chip voltage received by a chip is less than that of a reference chip voltage (that is, when the supply voltage is too low or less than desired);

FIG. 6 is a block diagram of a voltage scaling device according to another embodiment of the inventive concept;

FIG. 7 is a block diagram of a voltage scaling device according to another embodiment of the inventive concept;

FIG. 8 is a block diagram of a voltage scaling device according to another embodiment of the inventive concept;

FIG. 9 is a block diagram of a voltage scaling device according to another embodiment of the inventive concept;

FIG. 10 illustrates a look-up table (LUT) included in a voltage regulator of the voltage scaling device of FIG. 9;

FIG. 11 is a circuit diagram of a DLL according to an embodiment of the inventive concept;

FIG. 12 is a flowchart illustrating a method of regulating a voltage, according to an embodiment of the inventive concept;

FIG. 13 is a diagram illustrating a memory card according to an embodiment of the inventive concept;

FIG. 14 is a block diagram illustrating a case in which a semiconductor memory system according to an embodiment of the inventive concept is a solid state drive;

FIG. 15 is a block diagram illustrating a computing system including a semiconductor memory system, according to an embodiment of the inventive concept; and

FIG. 16 is a diagram illustrating a server system including the semiconductor memory system and a network system including the server system, according to an embodiment of the inventive concept.

### DETAILED DESCRIPTION OF THE EMBODIMENTS

The attached drawings for illustrating exemplary embodiments of the inventive concept are referred to in order to gain a sufficient understanding of the exemplary embodiments, the merits thereof, and the objectives accomplished by the implementation of the exemplary embodiments. Hereinafter, the exemplary embodiments will be described in detail with reference to the attached drawings. Like reference numerals in the drawings denote like elements, and sizes of elements may be enlarged or reduced for clarity.

The terms used in the present specification are merely used to describe particular embodiments, and are not intended to limit the inventive concept. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

While such terms as “first,” “second,” etc., may be used to describe various components, such components must not be limited to the above terms. The above terms are used only to distinguish one component from another. For example, a first element may be named as a second element and a second element may be named as a first element without deviating from the range of the inventive concept.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

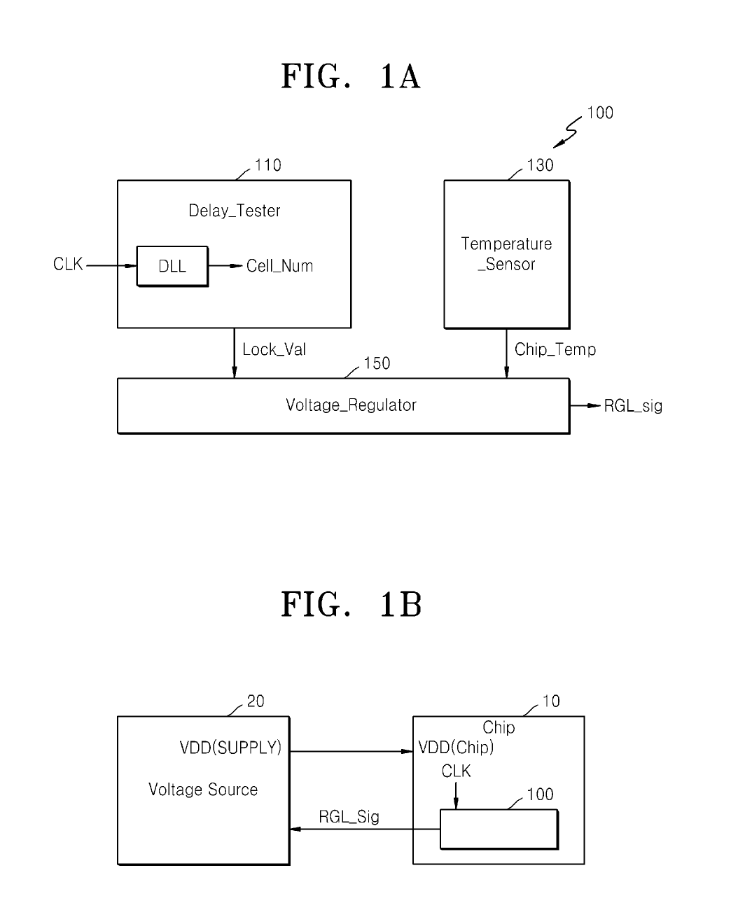

FIG. 1A is a block diagram illustrating a voltage scaling device 100 according to an embodiment of the inventive concept.

Referring to FIG. 1A, voltage scaling device 100 includes a delay tester 110, a temperature sensor 130, and a voltage regulator 150.

Voltage scaling device 100 may be included in a semiconductor memory device or a memory controller. The semiconductor memory device may be a NAND flash memory. However, the present invention is not limited thereto, and the semiconductor memory device may be any of various different types of memory devices including a random access memory (RAM), a read-only memory (ROM), a synchronous dynamic random access memory (SDRAM), and a NOR flash memory, which may be provided as internal semiconductor integrated circuits in computers or electronic devices, a solid state disk (SSD), a hard disk drive (HDD), or other high capacity storage devices.

Delay tester 110 receives a clock signal CLK and outputs a locking value Lock_Val which represents the number of delay cells in a cascaded series of delay cells which cumulatively delay the clock signal CLK by one clock period, that is, the number of delay cells through which the clock signal CLK passes until it is delayed by at least one clock period. Delay tester 110 may include a delay locked loop (DLL). The clock signal CLK may be input to the DLL. The DLL may output a cell number Cell_Num of a delay cell at which a one period-delayed clock signal is output while the clock signal CLK is delayed through delay cells which are cascaded in series with each other in the DLL. The locking value Lock_Val may be the number of delay cells through which the clock signal CLK passes to a delay cell corresponding to the cell number Cell_Num. Each of the delay cells may include a delay buffer. The delay buffers of the delay cells are serially connected and delay the clock signal CLK. The clock signal CLK may be delayed for more than one clock period thereof while passing through a number of delay buffers. The locking value Lock_Val calculated by delay tester 110 may be input to voltage regulator 150.

Temperature sensor 130 measures the temperature of the semiconductor memory device. A temperature value Chip_Temp output from temperature sensor 130 may be input to voltage regulator 150.

Voltage regulator 150 receives the locking value Lock_Val and the temperature value Chip_Temp. Voltage regulator 150 senses a variation of a chip voltage VDD(chip) which the semiconductor memory device receives in response to the locking value Lock_Val and the temperature value Chip_Temp. If the locking value Lock_Val increases, it means that the chip voltage VDD(chip) received by the integrated circuit or chip, for example a semiconductor memory device, has also increased. If the locking value Lock_Val decreases, it means that the chip voltage VDD(chip) received by the integrated circuit or chip has also decreased. Voltage regulator 150 may output a voltage-regulated signal RGL_sig in response to the sensed variation of the chip voltage VDD(chip) received by the integrated circuit or chip. In addition, in another embodiment of the inventive concept, voltage regulator 150 may receive a supply voltage VDD(supply) of a voltage source and then output a regulated supply voltage. The regulated supply voltage may be input to the voltage source, and thus, the supply voltage VDD(supply) supplied by the voltage source may be increased or decreased. In addition, in another embodiment of the inventive concept, voltage regulator 150 may output a difference between the supply voltage VDD(supply) and the regulated supply voltage. The difference between the supply voltage VDD(supply) and the regulated supply voltage may be input to the voltage source, and thus, the voltage source may increase or decrease the supply voltage VDD(chip) as necessary.

Referring to FIG. 1A again, delay tester 110 may receive the clock signal CLK and then calculate the locking value Lock_Val through the cell number Cell_Num of a delay cell at which a one period-delayed clock signal is output. Delay tester 110 transmits the locking value Lock_Val to voltage regulator 150. Temperature sensor 130 measures the temperature value Chip_Temp of the semiconductor memory device. The temperature value Chip_Temp calculated by temperature sensor 130 is transmitted to voltage regulator 150. Voltage regulator 150 outputs the voltage-regulated signal RGL_sig in response to the received locking value Lock_Val and temperature value Chip_Temp.

FIG. 1B illustrates an integrated circuit, in particular a semiconductor memory device 10, including voltage scaling device 100, according to the embodiment of the inventive concept.

Referring to FIG. 1B, the semiconductor memory device 10 (hereinafter, referred to as a chip 10) includes voltage scaling device 100 of FIG. 1A. In addition, chip 10 receives a chip voltage VDD(chip) from a voltage source 20. If the supply voltage supplied from voltage source 20 has a level VDD(supply), then the chip voltage which is actually received by chip 10 may be changed to be a chip voltage VDD(chip) which may be greater or less than VDD(supply). This change may depend on temperature and other environmental factors. Delay tester 110 measures a chip voltage VDD(chip) received by chip 10 through a delay value of the DLL. For example, if the chip voltage VDD(chip) received by chip 10 increases from 2.1 volts to 2.3 volts, the delay value of the DLL also increases and thus the locking value Lock_Val increases. For example, the locking value Lock_Val may increase from 4 to 6. In this case, if voltage regulator 150 controls voltage source 20 so as to reduce its output voltage VDD(supply) from 2.1 volts to 1.9 volts, then the chip voltage VDD(chip) which is received by chip 10 may be stabilized from 2.3 volts to 2.1 volts. The voltage-regulated signal RGL_sig of FIGS. 1A-B may provide voltage source 20 with information for decreasing the supply voltage VDD(supply) which is supplied from voltage source 20 from 2.1 volts to 1.9 volts. Thus, voltage scaling device 100 according to the embodiment of the inventive concept may control voltage source 20 to insure that chip 10 receives a stable chip voltage VDD(chip) by monitoring the chip voltage VDD(chip) which is received by chip 10, by using the DLL.

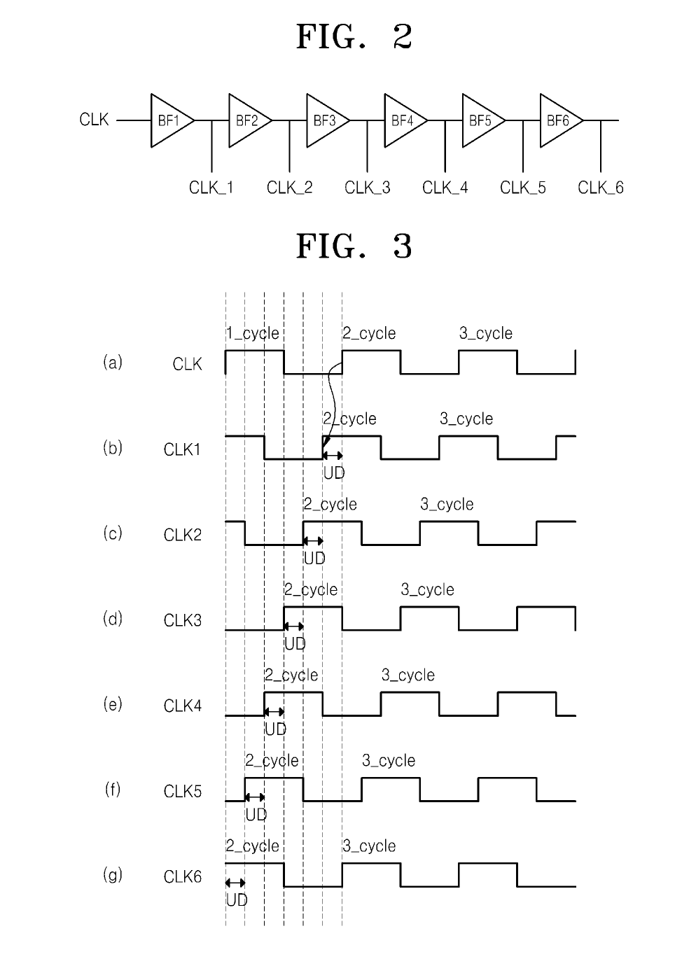

FIGS. 2 through 5 are diagrams for explaining an operation of voltage scaling device 100 of FIG. 1.

FIG. 2 illustrates delay buffers of the DLL, and FIG. 3 illustrates clock signals of input terminals or output terminals of the delay buffers.

Referring to FIG. 2, if a reference clock signal CLK is input to a first delay buffer BF1 and passes through first delay buffer BF1, the reference clock signal CLK is delayed by a unit delay and thus a first clock signal CLK_1 is generated. Here, a unit delay is a delay time that occurs when the reference clock signal CLK passes through one delay buffer. For example, the unit delay may be 0.5 ns, 1 ns, 2 ns, 10 ns, 100 ns, etc. Since the period of the reference clock signal CLK is constant, the number of delay buffers which are necessary to delay the reference clock signal CLK by at least one clock period is determined based on the size of the unit delay. Thus, it is possible to determine the size of the unit delay by calculating the number of delay buffers which are necessary in order to delay the reference clock signal CLK by at least one clock period. In FIG. 2, six delay buffers are illustrated. However, this number of delay buffers is just exemplary and does not limit the scope of the inventive concept.

The first clock signal CLK_1 is input to a second delay buffer BF2 and delayed by the unit delay through second delay buffer BF2, and thus, a second clock signal CLK_2 is generated. The second clock signal CLK_2 is input to a third delay buffer BF3 and delayed by the unit delay through third delay buffer BF3, and thus, a third clock signal CLK_3 is generated. The third clock signal CLK_3 is input to a fourth delay buffer BF4 and delayed by the unit delay through fourth delay buffer BF4, and thus, a fourth clock signal CLK_4 is generated. The fourth clock signal CLK_4 is input to a fifth delay buffer BF5 and delayed by the unit delay through fifth delay buffer BF5, and thus, a fifth clock signal CLK_5 is generated. The fifth clock signal CLK_5 is input to a sixth delay buffer BF6 and delayed by the unit delay through sixth delay buffer BF6, and thus, a sixth clock signal CLK_6 is generated.

FIGS. 3A through 3G illustrate the first clock signal CLK_1 through the sixth clock signal CLK_6 and the reference clock signal CLK.

The second clock signal CLK_2 is delayed by one unit delay, compared to the first clock signal CLK_1. The third clock signal CLK_3 is delayed by one unit delay, compared to the second clock signal CLK_2. The fourth clock signal CLK_4 is delayed by one unit delay, compared to the third clock signal CLK_3. The fifth clock signal CLK_5 is delayed by one unit delay, compared to the fourth clock signal CLK_4. The sixth clock signal CLK_6 is delayed by one unit delay, compared to the fifth clock signal CLK_5. In the result, the sixth clock signal CLK_6 is delayed by one clock period, compared to the reference clock signal CLK.

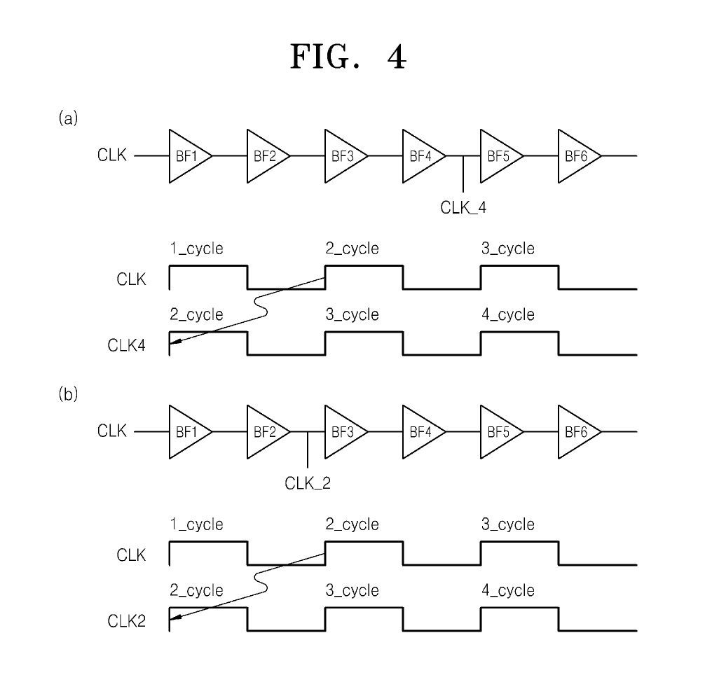

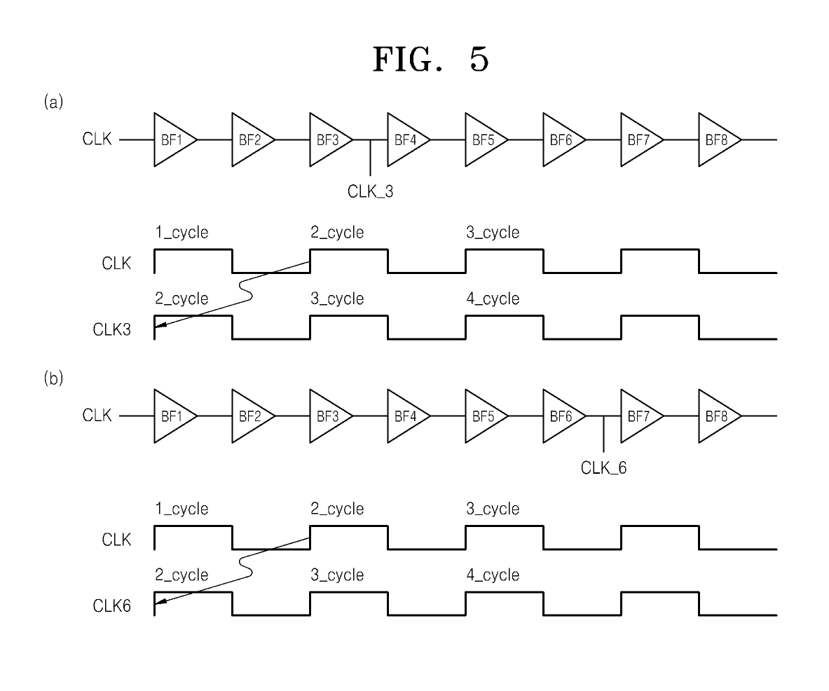

FIGS. 4A and 4B are diagrams for explaining a process of increasing the level of a supply voltage VDD(supply) of the voltage source when the level of the voltage VDD(chip) received by the chip is greater than that of a reference chip voltage VDD(chip)_{REF} (that is, when the supply voltage VDD(supply) is too high or higher than desired). In the discussion to follow, is assumed that a reference locking value Ref_Lock_Val (refer to FIG. 7) is 2. The reference locking value Ref_Lock_Val means the number of delay cells required to delay the clock signal CLK for one clock period when the chip voltage VDD(chip) received by the chip equals the reference chip voltage VDD(chip)_{REF}.

Referring to FIG. 4A, there is a difference of one clock period between the reference clock signal CLK and the fourth clock signal CLK_4. That is, the reference clock signal CLK is continuously delayed while passing through first delay buffer BF1 through fourth delay buffer BF4, and thus, the fourth clock signal CLK_4 which is output from fourth delay buffer BF4 has the same phase as the reference clock signal CLK. Thus, the locking value Lock_Val is 4, compared to the reference locking value Ref_Lock_Val which is 2 in this example, as mentioned above. Thus, this is a state in which the chip voltage VDD(chip) received by the chip is higher than a reference chip voltage VDD(chip)_{REF} (that is, a state in which the supply voltage VDD(supply) is too high or greater than desired). Thus, it is necessary to decrease the supply voltage VDD(supply) of the voltage source.

FIG. 4B illustrates a state in which the supply voltage VDD(supply) has been decreased by feeding back the result of FIG. 4A. There is a difference of one clock period between the reference clock signal CLK and the second clock signal CLK_2. Thus, the locking value Lock_Val is 2. Since the reference locking value Ref_Lock_Val is 2 as assumed above, the reference locking value Ref_Lock_Val and the locking value Lock_Val in the state in which the supply voltage VDD(supply) has been decreased are equal to each other. Thus, voltage scaling device 100 of the semiconductor memory device may ensure a stable chip voltage VDD(chip) without consuming more power than needed.

FIGS. 5A and 5B are diagrams for explaining a process of increasing a level of a chip voltage VDD(chip) received by the chip when the level of the chip voltage VDD(chip) is less than that of a reference chip voltage VDD(chip)_{REF} (that is, when the supply voltage VDD(supply) is too high or higher than desired). Here, it is assumed that a reference locking value Ref_Lock_Val is 6.

Referring to FIG. 5A, there is a difference of one clock period between the reference clock signal CLK and the third clock signal CLK_3. That is, the reference clock signal CLK is continuously delayed while passing through first delay buffer BF1 through third delay buffer BF3, and thus, the third clock signal CLK_3 which is output from third delay buffer BF3 has the same phase as the reference clock signal CLK. Thus, the locking value Lock_Val is 3, compared to the reference locking value Ref_Lock_Val which is 6 in this example, as mentioned above. Thus, this is a state in which the chip voltage VDD(chip) received by the chip is less than a reference chip voltage VDD(chip)_{REF} (that is, a state in which the supply voltage VDD(supply) is too low or less than desired). Thus, it is necessary to increase the supply voltage VDD(supply) of the voltage source.

FIG. 5B illustrates a state in which the supply voltage VDD(supply) has been increased by feeding back the result of FIG. 5A. There is a difference of one clock period between the reference clock signal CLK and the sixth clock signal CLK_6. Thus, the locking value Lock_Val is 6. Since the reference locking value Ref_Lock_Val is 6 as assumed above, the reference locking value Ref_Lock_Val and the locking value Lock_Val in the state in which the supply voltage VDD(supply) has been increased are equal to each other. Thus, voltage scaling device 100 of the semiconductor memory device may ensure a stable chip voltage having a level required by the semiconductor memory device.

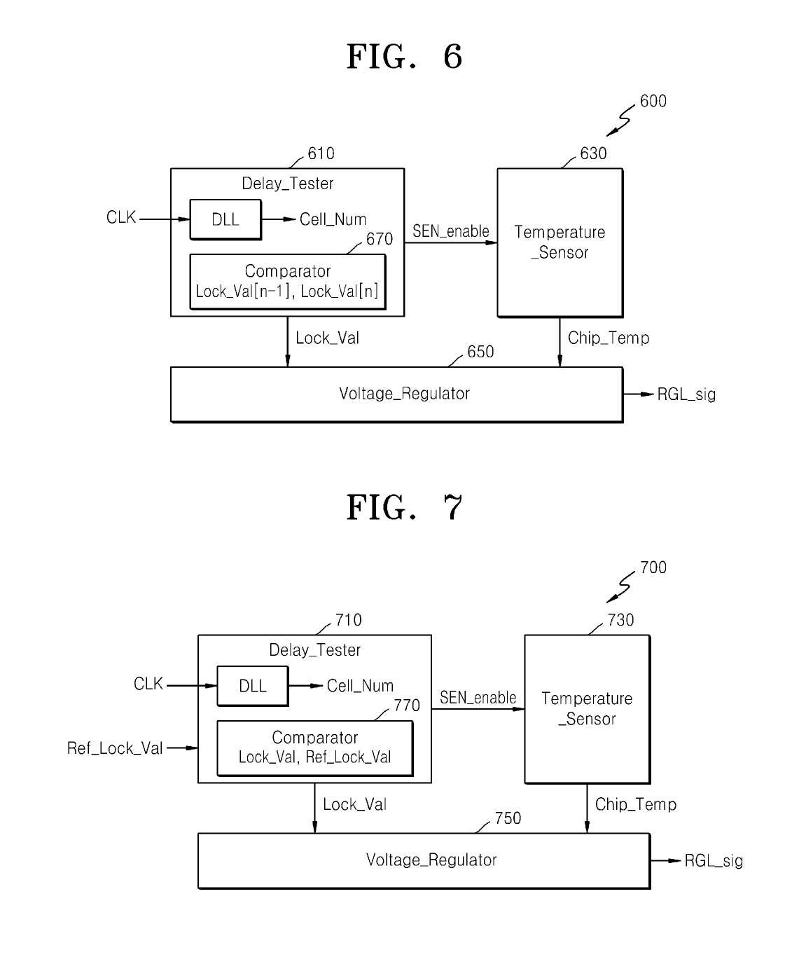

FIG. 6 is a block diagram of a voltage scaling device 600 according to another embodiment of the inventive concept.

Referring to FIG. 6, voltage scaling device 600 includes a delay tester 610, a temperature sensor 630, and a voltage regulator 650. Temperature sensor 630 and voltage regulator 650 substantially perform the same functions as temperature sensor 130 and voltage regulator 150 of FIG. 1, respectively. Delay tester 610 includes a comparator 670. Delay tester 610 periodically calculates a locking value Lock_Val at rising edges or falling edges of a clock signal CLK. The periodically calculated locking values Lock_Val are stored in comparator 670 in turn. Comparator 670 compares a locking value Lock_Val[n-1] calculated in a n-1-th period with a locking value Lock_Val[n] calculated in a n-th period (here, n is an integer which is more than 2). If the locking value Lock_Val[n-1] calculated in the n-1-th period and the locking value Lock_Val[n] calculated in the n-th period by receiving an update signal are different from each other, then the locking value Lock_Val [n] is sent to voltage regulator 650 as the locking value Lock_Val, and an enable signal SEN_Enable for enabling temperature sensor 630 is generated and output to temperature sensor 630. Thus, temperature sensor 630 may not continuously measure temperature but measure the temperature only if necessary. Thus, power consumption is reduced by preventing an unnecessary operation.

FIG. 7 is a block diagram of a voltage scaling device 700 according to another embodiment of the inventive concept.

Referring to FIG. 7, voltage scaling device 700 includes a delay tester 710, a temperature sensor 730, and a voltage regulator 750. Temperature sensor 730 and voltage regulator 750 are substantially the same as temperature sensor 130 and voltage regulator 150 of FIG. 1, respectively. Delay tester 710 includes a comparator 770. Delay tester 710 receives a reference locking value Ref_Lock_Val. If a locking value Lock_Val[n-1] calculated by delay tester 710 and the reference locking value Ref_Lock_Val are different from each other, then an enable signal SEN_Enable for enabling temperature sensor 730 is generated and output to temperature sensor 730. Temperature sensor 730 is enabled in response to the enable signal SEN_Enable and measures the temperature of the semiconductor memory device. Thus, temperature sensor 730 may not continuously measure the temperature but measure the temperature only if necessary. Thus, power consumption is reduced by preventing an unnecessary operation.

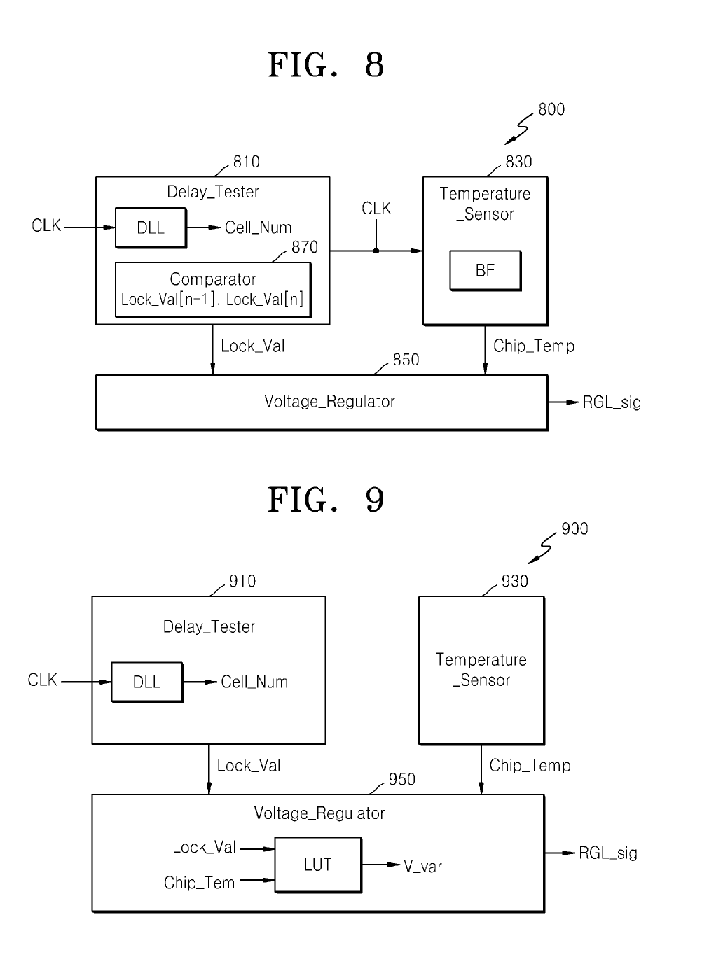

FIG. 8 is a block diagram of a voltage scaling device 800 according to another embodiment of the inventive concept.

Referring to FIG. 8, voltage scaling device 800 includes a delay tester 810, a temperature sensor 830, and a voltage regulator 850. Voltage regulator 850 is substantially the same as voltage regulator 150 of FIG. 1, respectively. Delay tester 810 receives a clock signal CLK and periodically calculates a locking value Lock_Val and the temperature of the semiconductor memory device at rising edges or falling edges of the clock signal CLK. The periodically calculated locking values Lock_Val are processed as in the embodiment of FIG. 6. Thus, it is possible to calculate the locking value Lock_Val and a temperature value Chip_Temp of the semiconductor memory device by using one clock signal. In another embodiment of the inventive concept, the temperature value Chip_Temp of the semiconductor memory device, periodically calculated at rising edges or falling edges of the clock signal CLK, is continuously stored in a buffer BF. In another embodiment of the inventive concept, the stored temperature value Chip_Temp may be updated and then an updated temperature value may be stored in buffer BF.

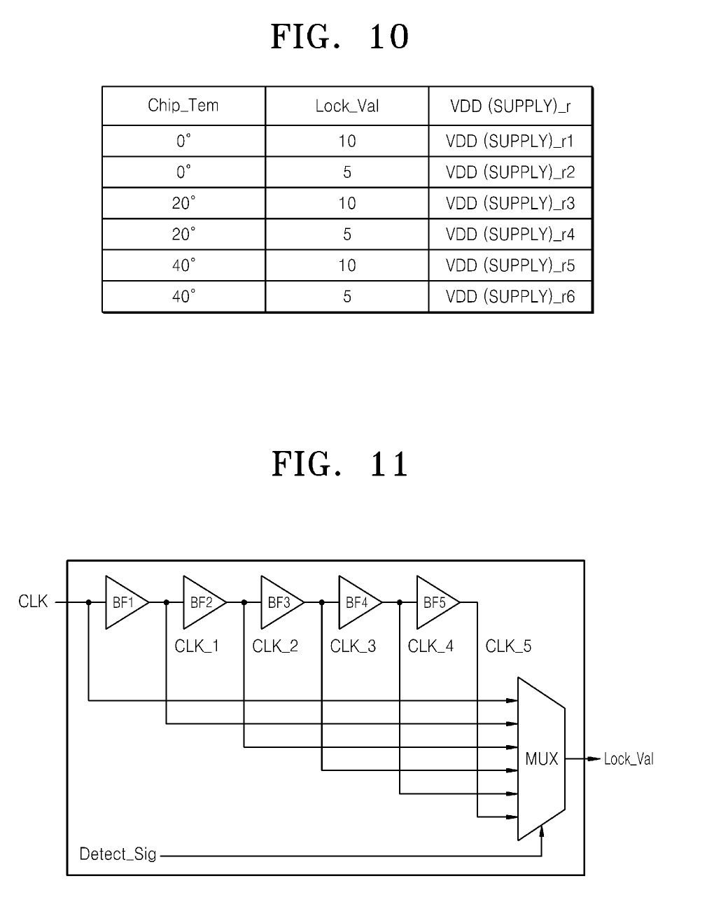

FIG. 9 is a block diagram of a voltage scaling device 900 according to another embodiment of the inventive concept. FIG. 10 illustrates a look-up table (LUT) included in a voltage regulator 950 of voltage scaling device 900.

Referring to FIG. 9, voltage scaling device 900 includes a delay tester 910, a temperature sensor 930, and voltage regulator 950. Voltage regulator 950 includes look-up table (LUT) of FIG. 10. Look-up table LUT of FIG. 10 may include a reference supply voltage value VDD(supply)_r which should be supplied for temperature value Chip_Temp of the semiconductor memory device and a locking value Lock_Val. Thus, it is possible to calculate a level of the supply voltage value VDD(supply)_r which should be supplied, in response to the locking value Lock_Val received from delay tester 910 and the temperature value Chip_Temp received from temperature sensor 930. In addition, it is possible to calculate a difference (that is, a voltage variation V_var) between the reference supply voltage value VDD(supply)_r which should be supplied and a current supply voltage VDD(supply). Thus, voltage regulator 950 may rapidly regulate the supply voltage VDD(supply) depending on a corresponding temperature value Chip_Temp and locking value Lock_Val. In addition, look-up table LUT may be stored in the semiconductor memory device during the manufacture of the semiconductor memory device. In addition, look-up table LUT may be set or updated by a user.

Referring to FIG. 10, reference supply voltage values VDD(supply)_r1 through VDD(supply)_r6, which are supplied for the temperature value Chip_Temp of the semiconductor memory device and the locking value Lock_Val, are stored in look-up table LUT. That is, when the temperature value Chip_Temp is 0° Celsius and the locking value Lock_Val is 10, the reference supply voltage is VDD_r1. When the temperature value Chip_Temp is 0° Celsius and the locking value Lock_Val is 5, the reference supply voltage is VDD_r2. When the temperature value Chip_Temp is 20° and the locking value Lock_Val is 10, the reference supply voltage is VDD_r3. When the temperature value Chip_Temp is 20° and the locking value Lock_Val is 5, the reference supply voltage is VDD_r4. When the temperature value Chip_Temp is 40° and the locking value Lock_Val is 10, the reference supply voltage is VDD_r5. When the temperature value Chip_Temp is 40° and the locking value Lock_Val is 5, the reference supply voltage is VDD_r6. However, this look-up table LUT is just exemplary and does not limit the scope of the inventive concept.

FIG. 11 is a circuit diagram of a DLL according to an embodiment of the inventive concept.

Referring to FIG. 11, a reference clock signal CLK and a first clock signal CLK_1 through a fifth clock signal CLK_5 are input to a multiplexer MUX, and multiplexer MUX outputs a locking value Lock_Val in response to a detection signal Detect_Sig. The detection signal Detect_Sig is used to detect that the reference clock signal CLK is delayed by one clock period while the reference clock signal CLK passes through first through fifth delay buffers BF1 through BF5. Although the number of delay buffers is 5 in FIG. 11, the number of delay buffers is just exemplary and does not limit the scope of the inventive concept. For example, when the locking value Lock_Val is 3, the reference clock signal CLK, the first clock signal CLK_1, and the second clock signal CLK_2 may be logic high, namely “1”, and the third clock signal CLK_3 through the fifth clock signal CLK_5 may be logic low, namely “0”. In this case, multiplexer MUX may output 3.

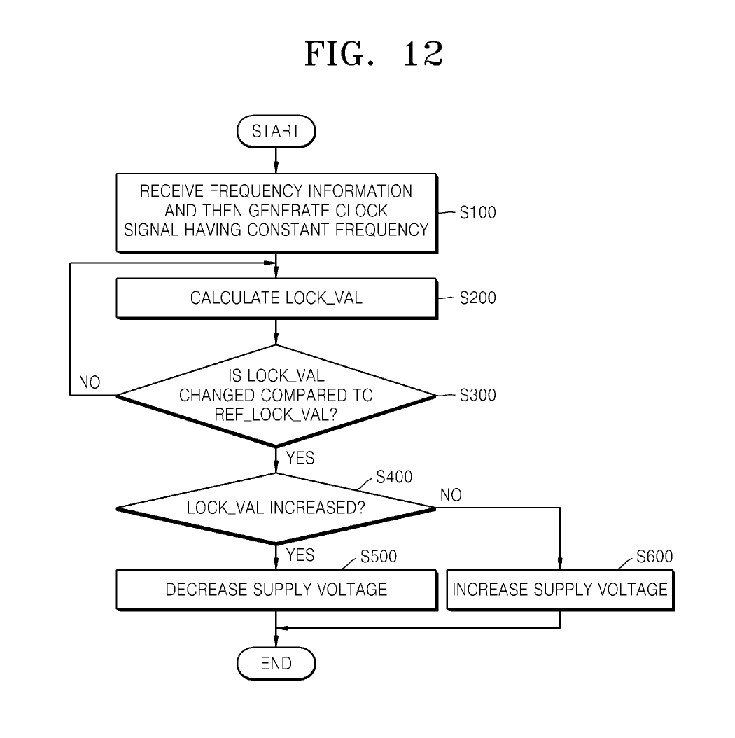

FIG. 12 is a flowchart illustrating a method of regulating a supply voltage VDD(supply) according to an embodiment of the inventive concept.

FIG. 12, first, delay tester 110 of FIG. 1A receives frequency information and then the DLL of delay tester 110 generates a clock signal having a constant frequency (operation S100). For example, a frequency of the DLL may be fixed at 200 MHz. Delay tester 110 calculates a locking value Lock_Val (operation S200). Delay tester 110 determines whether the locking value Lock_Val has changed by comparing the locking value Lock_Val with a reference locking value Ref_Lock_Val (operation S300). If the locking value Lock_Val has not changed, then operation S200 is repeated. Otherwise, if the locking value Lock_Val has changed, voltage regulator 150 of FIG. 1A determines whether the locking value Lock_Val has increased (operation S400). If the locking value Lock_Val has increased, voltage regulator 150 decreases a supply voltage VDD(supply) (operation S500). Otherwise, if the locking value Lock_Val has not increased, voltage regulator 150 increases the supply voltage VDD(supply) (operation S600).

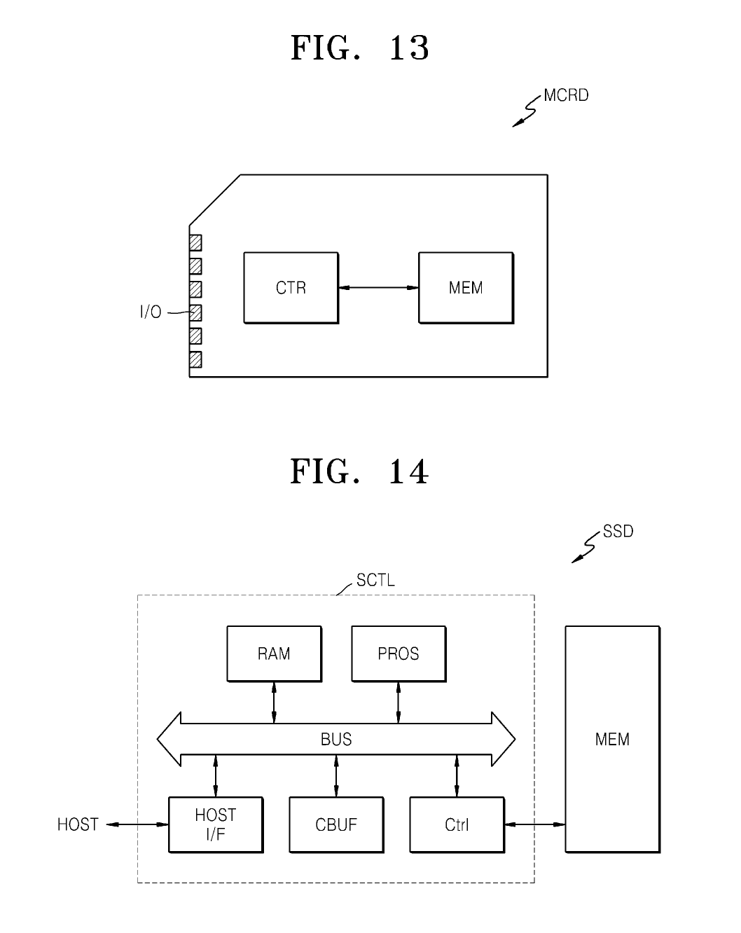

FIG. 13 is a diagram illustrating a memory card MCRD according to an embodiment of the inventive concept.

Referring to FIG. 13, memory card MCRD includes a memory controller CTRL and a memory device MEM. Memory controller CTRL or memory device MEM includes a voltage scaling device according an embodiment of the inventive concept. Memory controller CTRL controls a data writing to memory device MEM or a data reading from memory device MEM in response to a request received through an input and output unit I/O from an external host (not shown). In addition, in the case where memory device MEM of FIG. 13 is a flash memory device, memory controller CTRL controls an erasing operation of memory device MEM. Memory controller CTRL of memory card MCRD according to the present embodiment of the inventive concept may include interface units (not shown) for interfacing with the host device and memory device MEM, respectively, and a random access memory (RAM) (not shown) to perform the control operation. In particular, memory controller CTRL of memory card MCRD according to an embodiment of the inventive concept may include voltage scaling device 100 of FIG. 1 and the like. In addition, memory device MEM of memory card MCRD according to an embodiment of the inventive concept may include a voltage scaling device according to an embodiment of the inventive concept (e.g., voltage scaling device 100 of FIG. 1).

Memory card MCRD of FIG. 13 may be embodied as a compact flash card (CFC), a microdrive, a smart media card (SMC), a multimedia card (MMC), a security digital card (SDC), a memory stick, and a universal serial bus (USB) flash memory card.

FIG. 14 is a block diagram illustrating a case in which a semiconductor memory system according to an embodiment of the inventive concept is a solid state drive SSD.

Referring to FIG. 14, solid state drive SSD according to the present embodiment of the inventive concept includes a solid state drive controller SCTL and a memory device

MEM. Solid state drive controller SCTL or memory device MEM may include a voltage scaling device according to an embodiment of the inventive concept. Solid state drive controller SCTL may include a processor PROS, a random access memory RAM, a cache buffer CBUF, and a memory controller Ctrl, which are connected to each other via a bus BUS. Processor PROS controls so that memory controller CTRL transmits and receives data to and from memory device MEM in response to a request (commands, addresses, and data) of an external host (not shown). Processor PROS and memory controller CTRL of solid state drive SSD according to an embodiment of the inventive concept may be embodied in a single advanced reduced instruction set computer machilze (ARM) processor. Data required for an operation of processor PROS may be loaded to random access memory RAM.

A host interface HOST I/F receives the request of the host and then transmits the request to processor PROS, or transmits data received from memory device MEM to the host. Host interface HOST I/F may interface with the host by using various interface protocols such as universal serial bus (USB), man machine communication (MMC), peripheral component interconnect-express (PCI-E), serial advanced technology attachment (SATA), parallel advanced technology attachment (PATA), small computer system interface (SCSI), enhanced small device interface (ESDI), intelligent drive electronics (IDE), and the like. Data to be transmitted to memory device MEM or data transmitted from memory device MEM may be temporarily stored in cache buffer CBUF. Cache buffer CBUF may be a static random access memory SRAM and the like.

The aforementioned semiconductor memory device according to an embodiment of the inventive concept may be packaged by using various types of packages. For example, the semiconductor memory device may be packaged by using a package on package (POP), a ball grid array (BGA), a chip scale package (CSP), a plastic leaded chip carrier (PLCC), a plastic dual in-line package (PDIP), a die in waffle pack (DWP), a die in wafer form (DWF), a chip on board (COB), a ceramic dual in-line package (CERDIP), a plastic metric quad flat pack (MQFP), a thin quad flat pack (TQFP), a small outline (SOIC), a shrink small outline package (SSOP), a thin small outline (TSOP), a thin quad flat pack (TQFP), a system in package (SIP), a multi chip package (MCP), a wafer-level fabricated package (WFP), a wafer-level processed stack package (WSP), and the like.

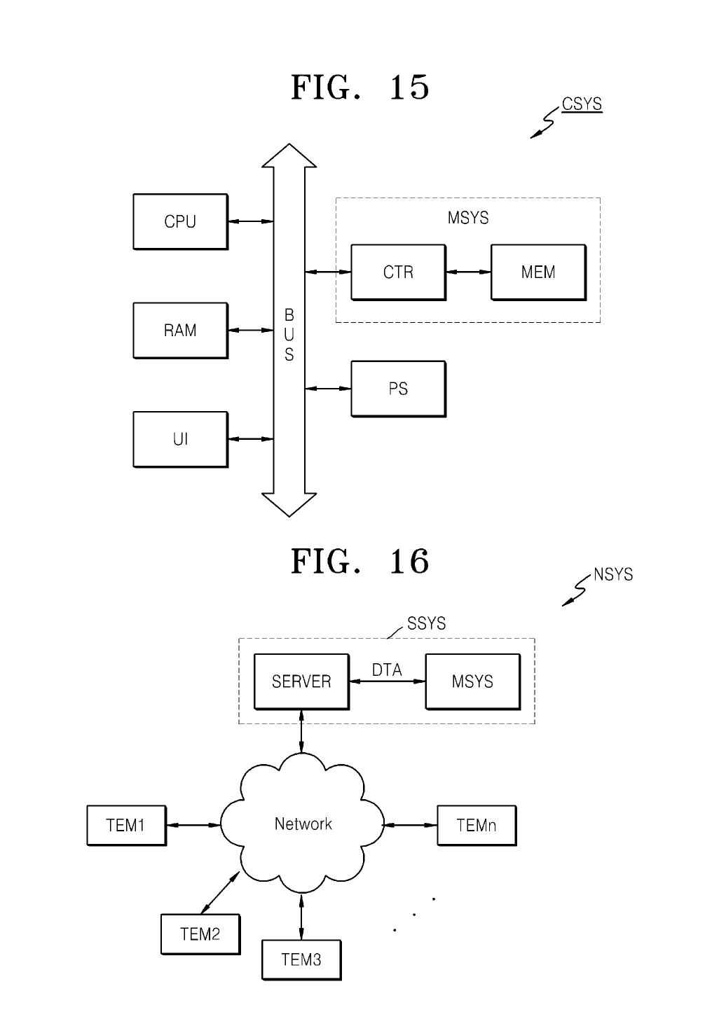

FIG. 15 is a block diagram illustrating a computing system CSYS including a semiconductor memory system MSYS, according to an embodiment of the inventive concept.

Referring to FIG. 15, in computing system CSYS, a processor CPU, a system memory RAM, and semiconductor memory system MSYS may be electrically connected to each other via a bus BUS. Semiconductor memory system MSYS includes a memory controller CTRL and a semiconductor memory device MEM. Memory controller CTRL or semiconductor memory device MEM may include a voltage scaling device according to an embodiment of the inventive concept (e.g., voltage scaling device 100 of FIG, 1). Semiconductor memory system MSYS of FIG. 15 may be semiconductor memory system MSYS of FIG. 13. In addition, computing system CSYS of FIG. 15 may further include a user interface UI and a power supply device PS which are electrically connected to each other via the bus BUS.

In the case where computing system CSYS of FIG. 13 according to an embodiment of the inventive concept is a mobile device, a battery for supplying an operating voltage to computing system CSYS and a modem such as a baseband chipset may be additionally provided. In addition, a camera image processor (CIS), a mobile dynamic random access memory, and the like may be further provided in computing system CSYS according to an embodiment of the inventive concept.

FIG. 16 is a diagram illustrating a server system SSYS including semiconductor memory system MSYS and a network system NSYS including server system SSYS, according to an embodiment of the inventive concept.

Referring to FIG. 16, network system NSYS may include server system SSYS and a plurality of terminals TEM1 through TEMn that are connected to each other through a network. Server system SSYS may include a server SERVER for processing requests received from the plurality of terminals TEM1 through TEMn and solid state drive SSD for storing data corresponding to the requests received from the plurality of terminals TEM1 through TEMn. Here, solid state drive SSD of FIG. 16 may be solid state drive SSD of FIG. 14.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims.

What is claimed is:

1. A voltage scaling device of a semiconductor memory device, the voltage scaling device comprising:
a delay tester configured to determine a number of delay cells of a delay locked loop (DLL) required to cumulatively delay a clock signal having a constant frequency, and which is input to the DLL, by one clock period;
a temperature sensor configured to measure a temperature of the semiconductor memory device; and
a voltage regulator configured to regulate a supply voltage of a voltage source which provides a chip voltage to the semiconductor memory device in response to the temperature measured by the temperature sensor and a locking value corresponding to the number of delay cells determined by the delay tester.

2. The voltage scaling device of claim 1, wherein the supply voltage is decreased when the number of delay cells required to cumulatively delay the clock signal by one clock period increases, and wherein the supply voltage is increased when the number of delay cells required to cumulatively delay the clock signal by one clock period decreases.

3. The voltage scaling device of claim 1, wherein, when the number of delay cells required to cumulatively delay the clock signal by one clock period is constant, the voltage regulator decreases the supply voltage when the temperature measured by the temperature sensor increases, and increases the supply voltage when the temperature measured by the temperature sensor decreases.

4. The voltage scaling device of claim 1, wherein the delay tester repeatedly determines, the number of delay cells required to cumulatively delay the clock signal by one clock period, and the temperature sensor measures the temperature of the semiconductor memory device when the number of delay cells required to cumulatively delay the clock signal by one clock period which is determined at a second time is different from the number of delay cells required to cumulatively delay the clock signal by one clock period which is determined at a first time before the second time.

5. The voltage scaling device of claim 1, wherein the temperature sensor measures the temperature of the semiconductor memory device when the number of delay cells required to cumulatively delay the clock signal by one clock period is different from a reference number of delay cells.

6. The voltage scaling device of claim 1, wherein the delay tester periodically determines, at predetermined periods, the number of delay cells required to cumulatively delay the clock signal by one clock period, and the temperature sensor measures, at the same predetermined periods, the temperature of the semiconductor memory device.

7. The voltage scaling device of claim 1, wherein the voltage regulator comprises a look-up table for storing reference supply voltage values corresponding to different numbers of delay cells required to cumulatively delay the clock signal by one clock period and a sensed temperature, and regulates the supply voltage with reference to the look-up table.

8. The voltage scaling device of claim 7, wherein the look-up table is stored in the semiconductor memory device during the manufacture of the semiconductor memory device.

9. The voltage scaling device of claim 7, wherein the look-up table is configured to be set by a user.

10. The voltage scaling device of claim 1, wherein the voltage regulator regulates the supply voltage within a predetermined voltage range and the predetermined range varies corresponding to the temperature measured by the temperature sensor.

11. The voltage scaling device of claim 1, wherein the DLL comprises a plurality of delay buffers and a multiplexer connected to the plurality of delay buffers,
wherein the multiplexer outputs the number of delay buffers which are required to delay the clock signal by one clock period.

12. The voltage scaling device of claim 1, wherein the semiconductor memory device comprises a NAND flash memory.

13. A semiconductor memory device comprising:
a controller comprising a voltage scaling device; and
a cell array receiving a voltage from the controller,
wherein the voltage scaling device comprises:
a delay tester configured to determine a number of delay cells of a delay locked loop (DLL) required to cumulatively delay a clock signal having a constant frequency, and which is input to the DLL, by one clock period;
a temperature sensor configured to measure a temperature of the semiconductor memory device; and
a voltage regulator configured to regulate a supply voltage of a voltage source which provides a chip voltage to the semiconductor memory device in response to the temperature measured by the temperature sensor and a locking value corresponding to the number of delay cells determined by the delay tester.

14. The semiconductor memory device of claim 13, wherein the supply voltage is decreased when the number of delay cells required to cumulatively delay the clock signal by one clock period increases, and the supply voltage is increased when the number of delay cells required to cumulatively delay the clock signal by one clock period decreases.

15. The semiconductor memory device of claim 13, wherein, when the number of delay cells required to cumulatively delay the clock signal by one clock period is constant, the voltage regulator decreases the supply voltage when the temperature measured by the temperature sensor increases, and increases the supply voltage when the temperature measured by the temperature sensor decreases.

16. An integrated circuit, comprising:
an input terminal configured to receive a chip voltage;
an output terminal configured to output a regulation signal for regulating a supply voltage of a voltage source which provides the chip voltage to the integrated circuit; and
a voltage scaling device, comprising:
a delay tester including a delay locked loop (loop) having a cascaded series of delay cells each having a unit delay, wherein the delay tester is configured to receive at its input a clock signal having a constant frequency and to cumulatively delay the clock signal as it passes through the cascaded series of delay cells, and wherein the delay tester is further configured to determine a number of the delay cells through which the clock signal passes until it is delayed by at least one clock period;
a temperature sensor configured to determine a temperature of the integrated circuit; and
a voltage regulator which is configured to produce the regulation signal in response to the temperature determined by the temperature sensor and further in response to the number of the delay cells through which the clock signal passes until it is delayed by at least one clock period.

17. The integrated circuit of claim 16, wherein the delay tester is further configured to compare the number of the delay cells through which the clock signal passes until it is delayed by at least one clock period with a reference number of delay cells, and to output to the voltage regulator a lock value signal indicating a difference between the number of the delay cells through which the clock signal passes until it is delayed by at least one clock period and the reference number of delay cells, and wherein the voltage regulator produces the regulation signal in response to the lock value signal.

18. The integrated circuit of claim 16, wherein the temperature sensor is configured to measure the temperature of the integrated circuit only when the number of the delay cells through which the clock signal passes until it is delayed by at least one clock period is different than the reference number of delay cells.

19. The integrated circuit of claim 16, wherein the delay tester is further configured to compare the number of the delay cells through which the clock signal passes until it is delayed by at least one clock period with a previously-determined number of the delay cells through which the clock signal previously passed until it was delayed by at least one clock period, and to output to the voltage regulator a lock value signal indicating a difference between the number of the delay cells through which the clock signal passes until it is delayed by at least one clock period and the previously-determined number of the delay cells through which the clock signal previously passed until it was delayed by at least one clock period, and wherein the voltage regulator produces the regulation signal in response to the lock value signal.

20. The integrated circuit of claim 16, wherein the voltage regulator comprises a look-up table storing a plurality of reference supply voltage values, and wherein the voltage regulator selects one of the stored reference supply values in response to the temperature determined by the temperature sensor and further in response to the number of the delay cells through which the clock signal passes until it is delayed by at least one clock period, and which is further configured to produce the regulation signal so as to cause the supply voltage of the voltage source to become equal to the selected reference supply value.
